(19) United States
(12) Patent Application Publication
(10) Pub. No.: US 2018/0067178 A1
(43) Pub. Date: Mar. 8, 2018

(54) MAGNETIC RESONANCE SIGNAL RECEIVING APPARATUS AND LOCAL COIL

(71) Applicant: Siemens Healthcare GmbH, Erlangen (DE)

(72) Inventors: Hong Cheng, Shenzhen (CN); Wen Ming Li, Shenzhen (CN); Zhi Bin Li, Shenzhen (CN); Tong Tong, Shenzhen (CN); JianMin Wang, Shenzhen (CN); Ying Lun Wang, Shenzhen (CN)

(73) Assignee: Siemens Healthcare GmbH, Erlangen (DE)

(21) Appl. No.: 15/696,500

(22) Filed: Sep. 6, 2017

(30) Foreign Application Priority Data
Sep. 6, 2016 (CN) 201621040235.4

(51) Int. Cl. G01R 33/341; G01R 33/36

(52) U.S. Cl. CPC G01R 33/341; G01R 33/3621

(57) ABSTRACT

A magnetic resonance signal receiving apparatus has a local coil, and an RF receiver connected thereto the local coil via a plug. The local coil has multiple antenna units, each separately receiving magnetic resonance signals generated by a subject in a magnetic resonance examination. The local coil also has a respective bandpass filter for each antenna unit. The local coil also has a time division multiplexer having multiple input ports respectively connected to the bandpass filters. Bandpass-filtered magnetic resonance signals that have passed through the bandpass filters are thus emitted as an output by just one output line according to multiplexing timeslot. The RF receiver has one or more RF receiving channels for receiving and processing the magnetic resonance signal from the output line of the local coil. The RF receiver is disposed close to the plug.

### BACKGROUND OF THE INVENTION

### Field of the Invention

The present invention concerns a magnetic resonance signal receiving apparatus and a local coil.

### Description of the Prior Art

FIG. 3 shows as an example a magnetic resonance signal reception link of a conventional local coil. In FIG. 3, one local coil 100 has M antenna units (coil elements) 101, each antenna unit 101 having its own amplifier 102 and its own output cable 103. Each local coil 100 is connected to a corresponding local coil cable via a plug 104 disposed on a patient table, etc. In addition, magnetic resonance signals from the antenna units 101 pass through a reception coil channel selector (RCCS) 200 and enter an RF receiver 300. The RCCS 200 is a switch array with L*M inputs and N outputs. Specifically, the RCCS 200 selects N magnetic resonance signals from magnetic resonance signals of L*M antenna units 101 and outputs same. In turn, the N output channels of the RCCS 200 are connected to N receiving channels of the RF receiver 300. In addition, the RF receiver 300 has an amplifier 301, a compressor 302, an analog-to-digital converter (ADC) 303 and a digital processing unit 304.

Thus, in the known technical solution described above, for the M antenna units in each local coil, it is necessary to provide M cables. Thus, there is a large number of cables which occupy a large volume, costs are high, and patients are not very comfortable when wearing the local coils.

Furthermore, in the technical solution described above, since the RF receiver needs to be equipped with multiple RF receiving channels, it has a large volume. It generally needs to be positioned close to the magnet, whereas the plugs are generally disposed on the patient table, therefore long RF cables are needed to connect the plugs to the RF receiver. In addition, to prevent interference with the magnet during imaging, RF shielding devices must be provided on the RF cables at intervals of a prescribed distance. Thus, for such RF cables of long length, it is also necessary to provide a large number of RF shielding devices.

### SUMMARY OF THE INVENTION

An object of the present invention is to provide a magnetic resonance signal receiving apparatus and a local coil that are capable of not only reducing the number of local coil cables by virtue of a simple structure, but also shortening the length of cables used to connect local coils with an RF receiver.

The invention encompasses the combination of a magnetic resonance signal receiving apparatus, used for magnetic resonance imaging equipment and has a local coil, and an RF receiver connected to the local coil via a plug. The local coil has multiple antenna units, capable of separately receiving magnetic resonance signals generated when a body under examination undergoes magnetic resonance examination and multiple bandpass filters, respectively connected individually to the antenna units, which subject magnetic resonance signals detected by the antenna units to bandpass filtering. The local coil also has a time division multiplexer that has multiple input ports connected separately to output terminals of the respective bandpass filters. Magnetic resonance signals that have passed through the bandpass filters are emitted as an output by just one output line according to a multiplexing timeslot.

The RF receiver has one or more RF receiving channels for receiving and processing the magnetic resonance signal from the output line of the local coil. The RF receiver being disposed close to the plug.

In the magnetic resonance signal receiving apparatus described above, the RF receiver and the plug are preferably disposed close to each other on a patient table of the magnetic resonance imaging equipment.

In the magnetic resonance signal receiving apparatus described above, preferably an amplifier, a compressor, an analog-to-digital conversion module and a digital processing unit are connected in series with each other in the RF receiving channel.

The magnetic resonance signal receiving apparatus described above preferably also has an optic fiber for connecting the RF receiver to a system receiver of the magnetic resonance imaging equipment.

The invention also encompasses just the local coil, which has multiple antenna units, capable of separately receiving magnetic resonance signals generated when a body under examination undergoes magnetic resonance examination and multiple bandpass filters, respectively connected to the antenna units, which subject magnetic resonance signals detected by the antenna units to bandpass filtering. The local coil again has a time division multiplexer, which has multiple input ports connected separately to output terminals of the bandpass filters. Magnetic resonance signals that have passed through the bandpass filters are emitted as an output by just one output line according to multiplexing timeslot.

The local coil described above also has multiple amplifiers, which subject the magnetic resonance signals detected by the antenna units to power amplification, and thus provide amplified magnetic resonance signals to the bandpass filters.

The provision of the time division multiplexer enables the number of local coil cables to be reduced, and the length of cable connecting the local coil to the RF receiver to be shortened.

### BRIEF DESCRIPTION OF THE DRAWINGS

FIG. 1 is a block diagram showing a local coil in accordance with the invention.

FIG. 2 is a block diagram showing a magnetic resonance signal receiving apparatus with an RF receiving apparatus in accordance with the invention.

FIG. 3 is a block diagram showing an existing local coil.

### DESCRIPTION OF THE PREFERRED EMBODIMENTS

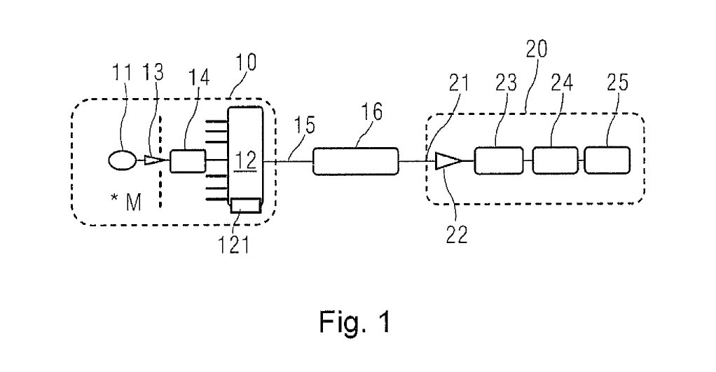

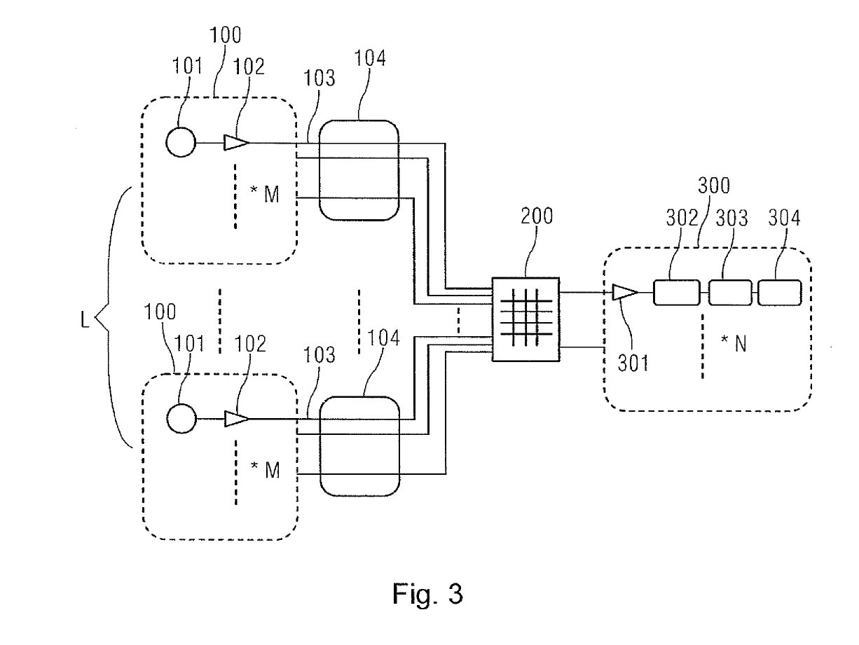

In order to keep the figures as uncluttered as possible, only one representation of a component is shown, even though that component may be present multiple times. In FIGS. 1 and 3, for example, the dashed lines are intended to indicate that the components that are shown once are actually present in each antenna unit.

FIG. 1 shows a local coil 10 having multiple antenna units 11 and a time division multiplexer 12. Each local coil 10 has M antenna units 11. In this embodiment, each antenna unit 11 is further connected to its own amplifier 13 and each amplifier 13 is connected to its own surface acoustic wave filter 14. The amplifier 13 amplifies the relatively weak magnetic resonance signal received by the antenna unit 11 connected thereto. The amplified magnetic resonance signal passes through the surface acoustic wave filter (SAWF) 14, so as to produce a filter signal of a certain bandwidth. The SAWF 14 is an RF signal processing device, principally composed of a piezoelectric substrate, and an input transducer and an output transducer on the substrate. The input transducer converts an input electric signal to a mechanical wave (inverse piezoelectric effect) that propagates along a surface of the piezoelectric substrate, which is converted to an electric signal at the output transducer (piezoelectric effect). By selecting an appropriate substrate material and weighting the two transducers, it is possible for signals of different frequencies to have different conversion efficiencies, so as to realize a frequency selection function (bandpass filtering). It should be noted that the use of the SAWF 14 to filter an amplified magnetic resonance signal is only an example, but the invention is not limited to the use of the SAWF. All that is needed is a bandpass filter capable of filtering an amplified magnetic resonance signal to obtain a signal with a certain bandwidth appropriate for the time division multiplexer 12.

Next, each magnetic resonance signal, processed by the amplifier 13 and the SAWF 14, is provided as an input to the time division multiplexer (TDM) 12. In this embodiment, detection signals from the antenna units 11 are provided as separate inputs to the time division multiplexer 12. The TDM 12 uses different time periods of the same physical connection to transmit different signals, to achieve the objective of multiplexing. Time division multiplexer 12 uses time as a parameter for signal division, such that different signals do not overlap with each other on the time axis. The time division multiplexer 12 divides the information transmission time provided for the entire channel into a number of time segments (timeslots), and allocates these timeslots to each signal source for use. Thus, using the time division multiplexer 12, magnetic resonance signals individually received by the multiple antenna units 11 can be provided as an output by just one output line 15. In addition, it should be noted that the time division multiplexer 12 also has a complex programmable logic device 121 (CPLD); using the CPLD 121, it is possible to select timeslots for use by the needed antenna units 11 according to control requirements of the MRI equipment. It should be noted that the CPLD 121 has been shown here as an example, but all that is needed is a programmable logic device capable of controlling the time division multiplexer 12.

Since the time division multiplexer 12 only provides an output of a magnetic resonance signal detected by one antenna unit 11 within one timeslot, the RF receiver 20 need only be equipped with one RF receiving channel 21. The RF receiving channel 21 of the RF receiver 20 is connected to the output line 15 of the local coil 10 via a plug 16, and provides the magnetic resonance signal detected by the antenna unit 11 as an output to the RF receiver 20. The magnetic resonance signal provided to the input of the RF receiver 20 is then provided as an input to an analog-to-digital converter 24 via an amplifier 22 and a compressor 23, and is converted to a digital signal, which is then processed by a digital processor 25. Here, the digital processor 25 may be a field programmable gate array, for example.

According to this embodiment, since the time division multiplexer 12 is provided, the magnetic resonance signal of just one antenna unit 11 is emitted as an output in a particular timeslot. Thus, the local coil 10 needs only one output line 15, so the volume and quantity of output cables of the local coil 10 are reduced, thereby lowering cable costs. In addition, correspondingly, for each local coil 10, the RF receiver 20 also needs only one RF receiving channel 21, so the cost of the RF receiver 20 can also be reduced.

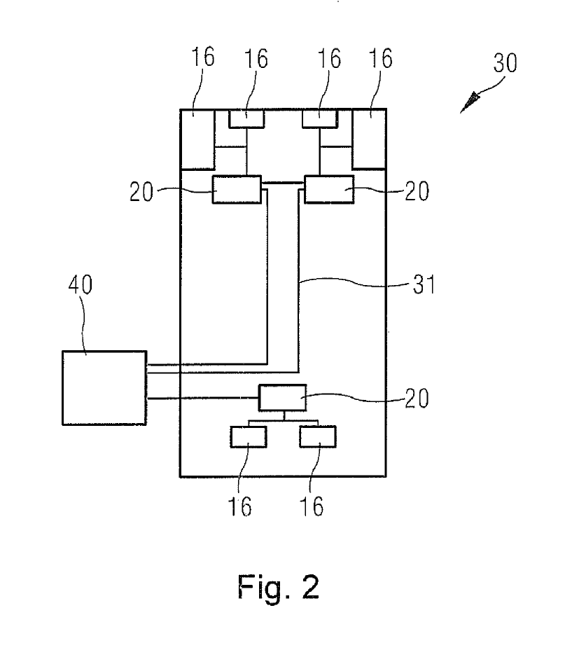

FIG. 2 shows as a block diagram of a magnetic resonance signal receiving apparatus 30 in which the RF receiver 20 described above is used. FIG. 2 shows multiple plugs 16 via which each local coil 10 (not shown) is connected to an RF receiver 20. In this embodiment, the provision of a separate time division multiplexer 12 for each local coil 10 enables multiple magnetic resonance signals detected by one local coil 10 to be provided as an output to the plug 16 by just one output line 15, and then provided to the RF receiver 20. As shown in FIG. 2, since each RF receiver 20 is connected to two plugs 16, i.e. connected to two local coils 10, two RF receiving channels 21 must be provided in each RF receiver 20.

In this embodiment, the number of RF receiving channels 21 needed by the RF receiver 20 is small, so the volume occupied is small, hence the RF receiver 20 can be disposed on the underside of the plugs 16 used for the local coils 10 on a patient table 30, and optical fibers 31 can be used to connect the RF receiver 20 to a receiver 40 of the magnetic resonance imaging system. The optical fibers 31 are only used to transmit digital signals outputted from the RF receiver 20. Thus, since the RF receiver 20 is disposed in proximity on the underside of the plugs 16, the RF cables used to connect the plugs 16 to the RF receiver 20 can be shortened, hence the number of RF shielding devices disposed on the RF cables can be reduced, thereby lowering costs.

Although modifications and changes may be suggested by those skilled in the art, it is the intention of the Applicant to embody within the patent warranted hereon all changes and modifications as reasonably and properly come within the scope of the Applicant's contribution to the art.

1. A magnetic resonance (MR) signal receiving apparatus comprising:
a local coil;
a radio-frequency (RF) receiver connected to the local coil via a plug;
said local coil comprising a plurality of antenna units, each antenna unit individually receiving MR signals produced by a subject undergoing an MR examination, a plurality of bandpass filters respectively individually connected to the antenna units in said plurality of antenna units, each bandpass filter subjecting the MR signal received by the respective antenna unit connected thereto to bandpass filtering, thereby producing a bandpass filtered MR signal, and a time division multiplexer comprising a plurality of input ports respectively connected individually to outputs of the bandpass filters in said plurality of bandpass filters, said time division multiplexer being configured to pass said bandpass filtered MR signals through said time division multiplexer so as to be emitted from said time division multiplexer via a single output line, according to a timeslot produced by said time division multiplexer; and
said RF receiver comprising at least one RF receiving channel disposed close to said plug that receives said MR bandpass signal from said output of said time division multiplexer, said at least one RF receiving channel performing a processing operation on said bandpass filtered MR signal from said output line.

2. An MR signal receiving apparatus as claimed in claim 1 wherein said RF receiver and said plug are disposed close to each other on a patient table of an MR scanner.

3. An MR signal receiving apparatus as claimed in claim 3 wherein said at least one receiving channel comprises an amplifier, a compressor, an analog-to-digital converter, and a digital processor connected in series.

4. An MR signal receiving apparatus as claimed in claim 1 wherein said RF receiver has an output with an optical fiber connected thereto, adapted to provide the MR bandpass filtered signal processed by the RF receiver to a system receiver of an MR system.

5. A local coil for use in magnetic resonance (MR) imaging, said local coil comprising:
a plurality of antenna units;
each antenna unit individually receiving MR signals produced by a subject undergoing an MR examination;
a plurality of bandpass filters respectively individually connected to the antenna units in said plurality of antenna units, each bandpass filter subjecting the MR signal received by the respective antenna unit connected thereto to bandpass filtering thereby producing a bandpass filtered MR signal; and
a time division multiplexer comprising a plurality of input ports respectively connected individually to outputs of the bandpass filters in said plurality of bandpass filters, said time division multiplexer being configured to pass said bandpass filtered MR signals through said time division multiplexer so as to be emitted from said time division multiplexer via a single output line, according to a timeslot produced by said time division multiplexer.

6. A local coil as claimed in claim 5 comprising a plurality of amplifiers respectively individually connected between each antenna unit and each bandpass filter.
